(19) United States
(12) Patent Application Publication
(10) Pub. No.: US 2026/0214830 A1
(43) Pub. Date: Jul. 23, 2026

(54) TRUNK CABLE BREAKOUT STORAGE AND PROTECTION ENCLOSURE

(71) Applicant: viaPhoton, Inc., Naperville, IL (US)

(72) Inventors: Yihan Zhang, Aurora, IL (US); Mark James Smrha, Chicago, IL (US); Nathan Eric Benton, Dallas, TX (US); Jeffrey Earl Jones, SR., Stewartstown, PA (US); Keith Samuel Maranto, Frankfort, IL (US)

(21) Appl. No.: 19/455,547

(22) Filed: Jan. 21, 2026

Related U.S. Application Data
(60) Provisional application No. 63/747,470, filed on Jan. 21, 2025.

(51) Int. Cl. H05K 7/14; G02B 6/44

(52) U.S. Cl. CPC H05K 7/1491; G02B 6/4429; G02B 6/4459

(57) ABSTRACT

A pulling container may include a housing and a cable manager configured to removably insert into the housing. The cable manager may include a breakout storage insert tray configured to provide support for at least one cable and including at least one storage space. The cable manager may also includes at least one connector organizer removably coupled to the breakout storage insert tray in the at least one storage space and configured to protection a connector on each of the at least one cable.

### CROSS-REFERENCE TO RELATED APPLICATION AND PRIORITY CLAIM

This application claims priority under 35 U.S.C. § 119(e) to U.S. Provisional Patent Application No. 63/747,470 filed on January 21, 2025, which is hereby incorporated by reference in its entirety.

### TECHNICAL FIELD

This disclosure relates generally to connectivity devices and processes. More specifically, this disclosure relates to a trunk cable breakout storage and protection enclosure.

### BACKGROUND

In modern data centers, the demand for high-capacity and reliable connectivity solutions has become increasingly critical. Data centers, especially in the case of hyperscale data centers, are required to support applications like artificial intelligence, machine learning, and associated massive data processing, all of which necessitate high-speed, low-latency communication. Traditionally, data centers have relied on fiber optic trunk cables to interconnect servers, storage, and networking equipment. These cables typically feature single or multifiber connectors that are manually installed at both ends, requiring careful handling when being pulled through cable conveyances to avoid damage to fiber connectors.

### SUMMARY

This disclosure provides a trunk cable breakout storage and protection enclosure.

In a first embodiment, a cable manager may include a breakout storage insert tray configured to provide support for at least one cable and including at least one storage space. The cable manager may also includes at least one connector organizer removably coupled to the breakout storage insert tray in the at least one storage space and configured to protection a connector on each of the at least one cable.

In a second embodiment, a pulling container may include a housing and a cable manager configured to removably insert into the housing. The cable manager may include a breakout storage insert tray configured to provide support for at least one cable and including at least one storage space. The cable manager may also includes at least one connector organizer removably coupled to the breakout storage insert tray in the at least one storage space and configured to protection a connector on each of the at least one cable.

In one or more of the above embodiments, the at least one connector organizer may include a base, and at least two guides that extend perpendicularly from the base and parallel to each other and are configured to provide protection for the connector for one of the at least one cable.

In one or more of the above embodiments, the at least one connector organizer may include three guides that extend perpendicularly from the base and parallel to each other and are configured to provide protection for two connectors for two of the at least one cable.

In one or more of the above embodiments, the breakout storage insert tray may further includes a plurality of tabs to support the at least one connector organizer.

In one or more of the above embodiments, the plurality of tabs may each include a slot. The at least one connector organizer may further includes a base, and a plurality of inserts extending from the base, each configured to insert into a respective slot of the plurality of tabs.

In one or more of the above embodiments, the breakout storage insert tray may further include at least one partition positioned around the storage space, each configured to protect one of the at least one connector organizer.

In one or more of the above embodiments, the at least one partition may provide a cable route for the cable to wrap around within the breakout storage insert tray.

In one or more of the above embodiments, the breakout storage insert tray may include three storage spaces. The at least one connector organizer can be removably coupled from any of the three storage spaces.

In one or more of the above embodiments, the breakout storage insert tray may further include at least one tie-down loop configured to reduce movement and displacement of the at least one cable during transportation and installation.

In one or more of the above embodiments, the cable manager may further include a strain relief connected to a back end of the breakout storage insert tray and configured to provide bend radius protection for the at least one cable.

Other technical features may be readily apparent to one skilled in the art from the following figures, descriptions, and claims.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example rack in accordance with this disclosure; and

FIGS. 2-5 illustrate an example pulling container in accordance with this disclosure.

### DETAILED DESCRIPTION

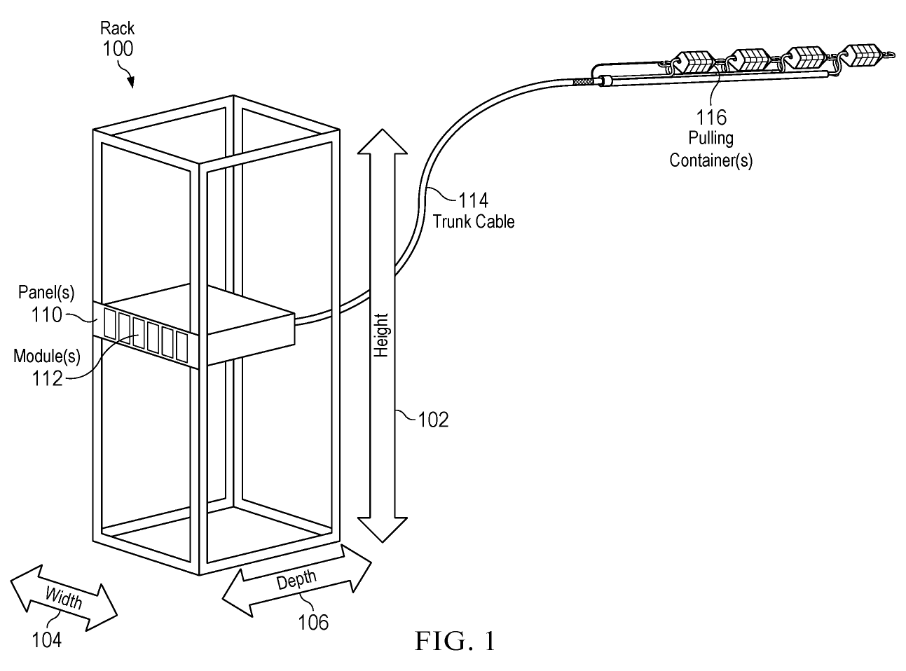

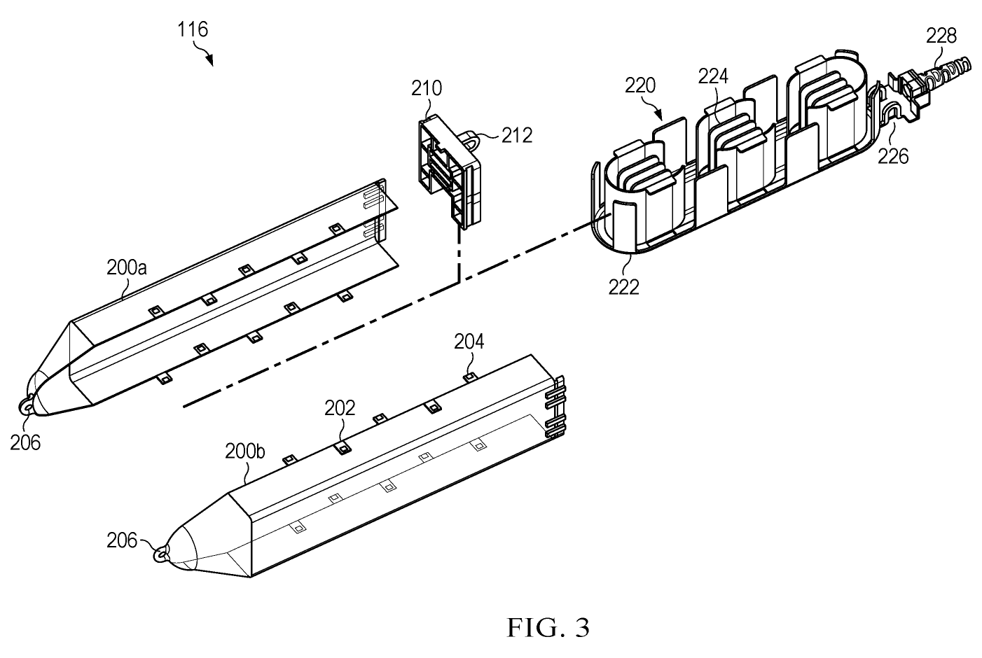

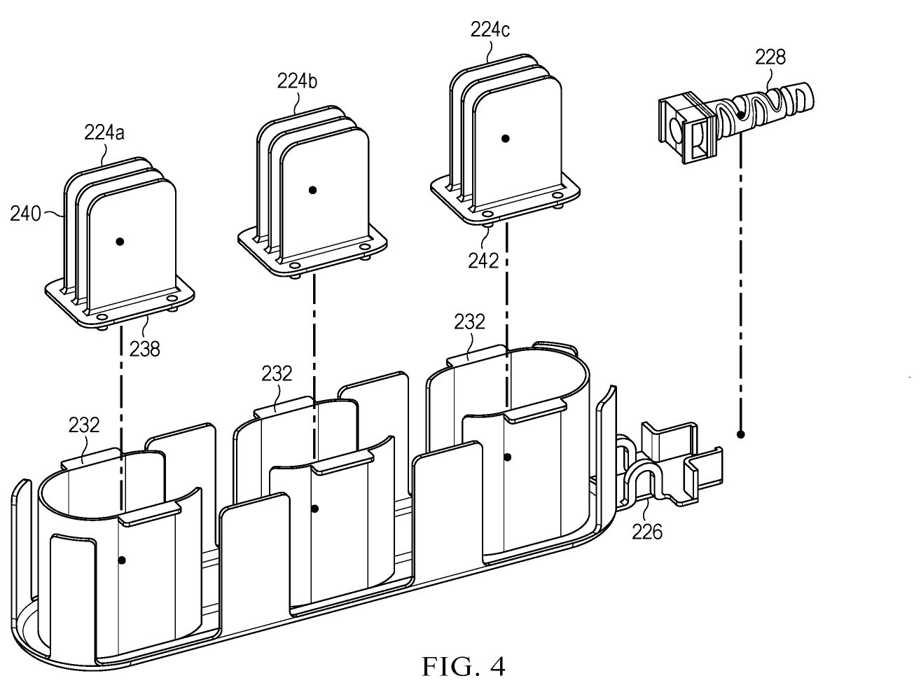

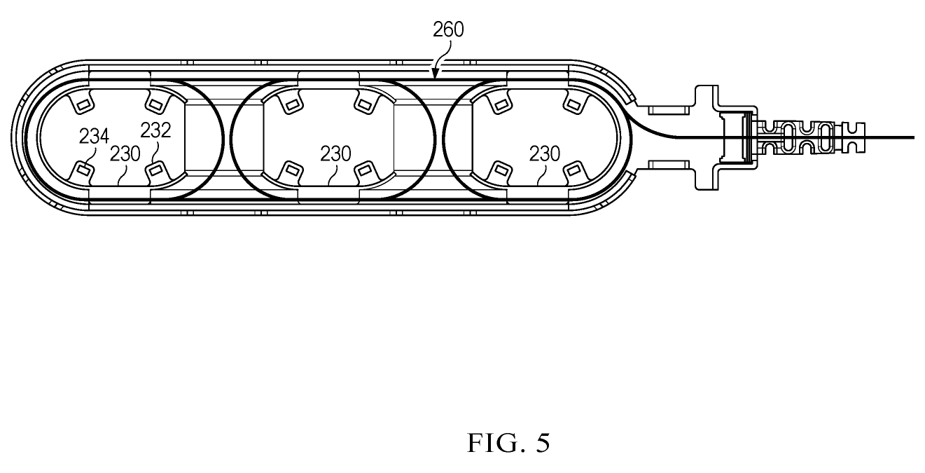

FIGS. 1 through 5, described below, and the various embodiments used to describe the principles of the present disclosure are by way of illustration only and should not be construed in any way to limit the scope of the disclosure. Those skilled in the art will understand that the principles of the present disclosure may be implemented in any type of suitably arranged device or system.

Current data center installations involve the manual pulling of fiber trunk cables through cable trays or ducts from one connection point to another. This process includes attaching a pulling sock to the fiber cable and pulling the cable through the tray, followed by unpacking and preparing the cable for connection.

The manual processes of installation, including cleaning, connecting, and assessing the cables, are time-consuming and prone to errors, leading to delays and potential rework. The manual steps introduce several challenges, including the risk of connector contamination, fiber damage, and connection errors. Furthermore, the use of pulling socks and additional protective materials generates waste and adds complexity to the process. These factors collectively contribute to higher labor costs, longer installation times, and increased risks of network downtime during the deployment phase.

With the ongoing expansion of data centers and the growing complexity of their infrastructure, the industry is searching for methods to streamline the fiber installation process while improving reliability and reducing labor requirements. The need for efficient, scalable solutions is becoming more urgent as the volume of fiber installations grows in line with demand for faster, higher-capacity networks.

The embodiments described herein provide a breakout storage and protection enclosure for managing fiber optic trunk cables and their associated breakout connectors. Traditional cable management systems often lack adequate protection for breakout connectors, leaving them vulnerable to damage from bending, crushing, dust intrusion, and other environmental hazards during shipping, storage, and installation. The current disclosure overcomes these deficiencies by integrating a protective pulling container with features that ensure both mechanical protection and efficient organization of the breakout cables and connectors, preventing damage caused by excessive bending or mechanical stress during handling and installation.

The breakout storage and protection enclosure further incorporates a modular and scalable architecture, which enables it to adapt to various network configurations and fiber densities. The breakout storage and protection enclosure includes an end cap with a loop mechanism for attaching additional units, allowing easy expansion and pulling of multiple modules. The breakout storage and protection enclosure includes a strain relief to protect cables from stress during pulling, ensuring compliance with bend radius requirements and reducing the risk of fiber breakage.

An integrated cable management and breakout storage tray within the modules store and secure cables and connectors while allowing easy labeling and access, ensuring that cables remain organized and undamaged throughout the process. Tie-down loops along the tray further stabilize the cables during transportation and installation.

FIG. 1 illustrates an example rack in accordance with this disclosure. Turning to FIG. 1, a rack is shown in accordance with one or more embodiments. The rack 100 is a piece of telecommunications equipment that provides for the housing and organization of diverse telecommunication devices.

The outer dimensions of rack 100, including rack width 104 and rack depth 106, align with the widths of most network and server equipment. For example, rack width 104 may measure 19 inches (48.26 cm) or 23 inches (58.42 cm) in width, standard measurements that are adhered to in the telecommunications industry. Other dimensions may be used, e.g., 21 inches, 23 inches, etc. The rack height 102, the rack width 104, and the rack depth 106 dimensions ensure that the rack 100 can accommodate equipment with different form factors, such as 1U, 2U, or larger units, where "U" represents a standard rack unit of measure equal to 1.75 inches in height.

The rack 100 may include a series of uniformly spaced vertical mounting slots, located on both the front and rear, to facilitate the arrangement and mounting of various telecommunication devices and components. The slots serve as attachment points for mounting the panels 110. The rack 100 may further be equipped with additional features such as ventilation openings and cable management.

Panels 110 are components that mount within the rack 100 to organize, secure, and provide access to connective hardware. Panels 110 are formed with standardized form factors for compatibility with the mounting slots of the rack 100. For example, panels 110 may include standardized mounting points to align with rack units, a layout that supports the intended cable or connector density, and provisions for labeling and user accessibility.

The panels 110 may be equipped with one or more modules 112 to secure the fibers using ports, connector adapters, connectors, etc. Modules 112 are prefabricated units or sub-assemblies designed for quick installation into the rack 100. The modules 112 may house electronic components, such as switches, routers, or patches. The modules 112 may include features for splicing, cable management, and security.

The dimensions of the modules 112 may conform to the standard dimensions of a rack 100. For example, the height of modules 112 may be 1 RU, or a multiple of the standard 1 RU dimension, e.g., 2 RU, 3 RU, etc. The width for each of the modules 112 may enable a group of the modules 112 to fit within one of the panels 110. For example, the width of each modules 112 may be selected such that a number of modules (e.g., 4, 6, 8, 10, 12, etc.) can be accommodated within the rack width 104.

The front end of the modules 112 is exposed through the front of one of the panels 110 and through the front of the rack 100. The front end of the modules 112 may include interfaces for power and data connectivity. For example, the modules 112 may include a group of the connector adapters to accommodate one or more optical connectors, such as LC connectors, SC connectors, ST connectors, etc.

The trunk cable 114 is a high-capacity fiber optic cable that connects various data center components. The trunk cable 114 provides the high-speed optical connections between network devices within the data center, ensuring low-latency data transmission. The trunk cable 114 typically contains multiple individual optical fibers, which may be housed within a protective sheath. The individual optical fibers can be made of silica glass. The sheath may comprise several layers of protective materials, such as buffer tubes, strength members, and a polyethylene outer jacket.

The pulling containers116 are modular enclosures that house one or more pre-terminated fiber modules, breakouts, or other fiber components during payout. The pulling containers 116 are linked together via a flexible linkage, which allows the containers to move through bends and curves in the data center’s cable trays or ducts. Multiple containers may be connected in series to form a continuous chain, allowing multiple containers, along with fiber components in case therein, to be pulled simultaneously during installation.

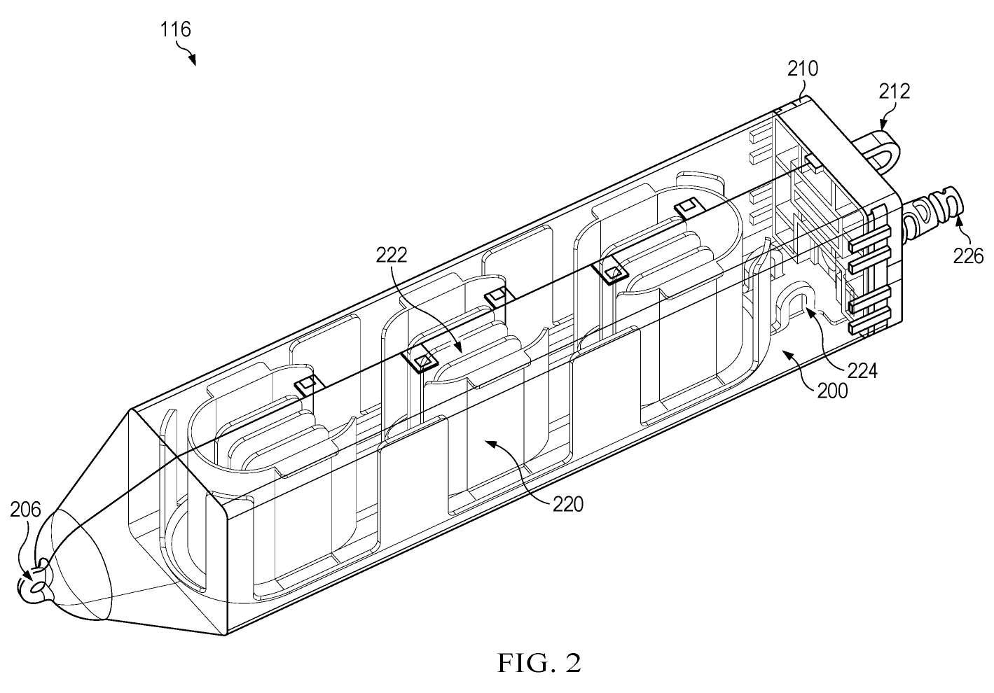

FIGS. 2-5 illustrate an example pulling container 116 in accordance with this disclosure. The pulling container shown in FIGS. 2-5 is one example of pulling container 116 shown in FIG. 1. As shown in FIG. 2, the pulling container 116 can include a housing 200 having a tubular structure that provides an internal space designed to organize and protect fiber optic breakout cables and connectors. This tubular structure of the housing 200 maintains a required bend radius to prevent damage to the cables during installation. The housing 200 may be formed from a suitably rigid material, including plastic, metal, wood, etc. In certain embodiments, the housing 200 is formed from plastic, which may be transparent. The housing 200 can be formed of multiple pieces, such as a first housing 200a and a second housing 200b. The housing 200 can include locking windows 202, retaining clips 204, and a front loop 206.

The locking windows 202 and the retaining clips 204 are features of the housing 200. In certain embodiments, the locking windows 202 are integrally formed into at least one of the first housing 200a and the second housing 200b. In certain embodiments, each locking window 202 can be rectangular openings configured to fit corresponding retaining clips 204. In certain embodiments, the retaining clips 204 that secures the first housing 202a to the second housing 202b. In certain embodiments, the locking windows 202 are positioned on the first housing 202a and the retaining clips 204 are positioned on the second housing 202b. In certain embodiments, the locking windows 202 and the retaining clips 204 alternate along edges of the first housing 202a and the second housing 202b.

The front loop 206 is positioned at one end of the pulling container 116 to facilitate the attachment of a pulling cord. In certain embodiments, the front loop 206 can include a hole through which a clip may be used to connect the pulling container 116 to a pulling cord so that the pulling container 116 may be pulled through an opening. In certain embodiments, the front loop 206 is an eyelet loop.

The pulling container 116 can also include an end cap 210 at the opposite end of the pulling container 116. The end cap 210 may be formed from a suitably rigid material, including plastic, metal, wood, etc. The end cap 210 prevents a cable manager 220 within the housing 200 from sliding out the back of the housing 200. The end cap 210 includes a back loop 212.

The end cap 210 includes a back loop 212 for attaching additional enclosures in series. In certain embodiments, the back loop 212 is an eyelet loop. The back loop 212 can enable modular scalability, allowing multiple pulling containers 116 to be linked together for larger installations. For example, a module connector can be coupled to the front loop 206 and the back loop 212. The module connector may be a carabiner. The module connector can be inserted through the front loop 206 of a first pulling container 116 and through the back loop 212 of a second pulling container 116.

Within the pulling container 116, a cable management, e.g. cable manager 220, is integrated. The cable manager 220 maintains an orderly arrangement during installation, ensuring that cables do not tangle or sustain damage. The cable manager 220 can include a breakout storage insert tray 222, connector organizers 224, tie-down loop 226, and a strain relief 228. The cable manager 220 can be inserted into the housing 200 of the pulling container 116. Once inside of the housing 200, the end cap 210 can be fitted at the end of the housing 200 to secure the cable manager 220.

The breakout storage insert tray 222 functions as the housing for the cable manager 220. The breakout storage insert tray 222 can be design to fit within the housing 200. The breakout storage insert tray 222 can include multiple cable storage spaces 230 that can each house a connector organizer 224. While illustrated as having three storage cable storage spaces 230, the breakout storage insert tray 222 can have any number of cable storage spaces 230. The breakout storage insert tray 222 can be formed of a suitably rigid material, including plastic, metal, wood, etc.

The storage spaces 230 of the breakout storage insert tray 222 are defined by partitions 232. Each storage space 230 can have a separate partition 232 that protects the cables that are secured to the cable managers 220. The partitions 232 can also define a cable route 260 for the breakout storage insert tray 222. Each cable stored in the connector organizers 224 can be wrapped around an outside of all of the partitions 232.

The breakout storage insert tray 222 can also include tabs 232 adjacent to each of the storage spaces 230. The tabs 232 can extend at a base of the insert tray 222. The tabs 232 can include slots 234. The slots 234 can have any shape including square, square, oval, etc.

Tie-down loops 226 are positioned along the cable manager 220 to secure cables reducing movement or displacement of cables during transportation or installation. Cables can be secured to the tie-down loops 226 using various materials such as aramid yarn, enhancing overall stability of the cables during installation.

The connector organizers 224 can be dedicated compartments or guides for systematically organizing and storing breakout cables and connectors. Connector organizers 224 are included to securely house individual connectors, support various connector types, and allow for easy labeling, access, and reconfiguration as needed. The connector organizers 224 can be individually inserted and removed from the breakout storage insert tray 222. The cable manager 220 can have one or more connector organizers 224. For example, the cable manager 220 can have a first cable manager 220a, a second cable manager 220b, and a third cable manager 220c. The first cable manager 220a can be inserted in any of the storage spaces 230 in the breakout storage insert tray 222. The second cable manager 220b can be inserted in one of the unoccupied storage spaces 230 in the breakout storage insert tray 222. The third cable manager 220c can be inserted in one of the storage spaces 230 not occupied by the first cable manager 220a and the second cable manager 220b.

The connector organizers 224 can include a base 238, guides 240, and inserts 242. The base 238 provides support for the cables situated in the connector organizers 224. The guides 240 extend perpendicularly from the base 238 and in parallel to each other guide 240. The connectors at the end of the cables can be stored in between guides 240 and the cable extending from the connectors can be wrapped around the guides 240. The connector organizers 224 can have at least two guides 240 for storing at least one cable. For example, the connector organizers 224 illustrated in FIGS. 2-5 have three guides 236 for storing two connectors and corresponding cables.

The connector organizers 224 can also have inserts 242 for coupling a connector organizer 224 to the breakout storage insert tray 222. The inserts 242 can have a shape corresponding to the slots 234 in the tabs 232 so that the inserts 242 can pass through the slots 234. The pulling containers 116 can include at least one combination of tabs 232 and inserts 242 for each of the storage spaces 230. The base 238 of the connector organizers 224 can be supported by the tabs 232. The inserts 242 can have a lip to lock the connector organizer 224 to the breakout storage insert tray 222. The inserts 242 can be adjusted to unlock the connector organizer from a opposite side of the tab 232. The base 238, guides 240, and inserts 242 may be formed from a suitably rigid material, including plastic, metal, wood, etc. Each of the base 238, guides 240, and inserts 242 can be formed of the same or different materials.

The pulling container 116 incorporates a strain relief 228 included on the cable manager 220. The strain relief 228 can provide bend radius protection for the cables that are routed through the pulling container 116. The strain relief 228 can help to maintain a proper bend radius of cables during storage and installation, thereby preventing fiber damage. The strain relief 228 can reduce mechanical stress on the cables, improving durability and integrity during handling or pulling operations.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. A cable manager comprising:
a breakout storage insert tray configured to provide support for at least one cable and including at least one storage space; and
at least one connector organizer removably coupled to the breakout storage insert tray in the at least one storage space and configured to protection a connector on each of the at least one cable.

2. The cable manager of claim 1, wherein the at least one connector organizer includes:
a base, and
at least two guides that extend perpendicularly from the base and parallel to each other and are configured to provide protection for the connector for one of the at least one cable.

3. The cable manager of claim 2, wherein the at least one connector organizer includes:
three guides that extend perpendicularly from the base and parallel to each other and are configured to provide protection for two connectors for two of the at least one cable.

4. The cable manager of claim 1, wherein the breakout storage insert tray further includes a plurality of tabs to support the at least one connector organizer.

5. The cable manager of claim 4, wherein:
the plurality of tabs each include a slot, and
the at least one connector organizer further includes:
a base, and
a plurality of inserts extending from the base, each configured to insert into a respective slot of the plurality of tabs.

6. The cable manager of claim 1, wherein the breakout storage insert tray further comprises:
at least one partition positioned around the storage space, each configured to protect one of the at least one connector organizer.

7. The cable manager of claim 6, wherein the at least one partition is configured to provide a cable route for the cable to wrap around within the breakout storage insert tray.

8. The cable manager of claim 1, wherein:
the breakout storage insert tray includes three storage spaces, and
the at least one connector organizer can be removably coupled from any of the three storage spaces.

9. The cable manager of claim 1, wherein the breakout storage insert tray further includes:
at least one tie-down loop configured to reduce movement and displacement of the at least one cable during transportation and installation.

10. The cable manager of claim 1, further comprising:
a strain relief connected to a back end of the breakout storage insert tray and configured to provide bend radius protection for the at least one cable.

11. A pulling container comprising:
a housing; and
a cable manager configured to removably insert into the housing, the cable manager comprising:
a breakout storage insert tray configured to provide support for at least one cable and including at least one storage space; and
at least one connector organizer removably coupled to the breakout storage insert tray in the at least one storage space and configured to protection a connector on each of the at least one cable.

12. The pulling container of claim 11, wherein the at least one connector organizer includes:
a base, and
at least two guides that extend perpendicularly from the base and parallel to each other and are configured to provide protection for the connector for one of the at least one cable.

13. The pulling container of claim 12, wherein the at least one connector organizer includes:
three guides that extend perpendicularly from the base and parallel to each other and are configured to provide protection for two connectors for two of the at least one cable.

14. The pulling container of claim 11, wherein the breakout storage insert tray further includes a plurality of tabs to support the at least one connector organizer.

15. The pulling container of claim 14, wherein:
the plurality of tabs each include a slot, and
the at least one connector organizer further includes:
a base, and
a plurality of inserts extending from the base, each configured to insert into a respective slot of the plurality of tabs.

16. The pulling container of claim 11, wherein the breakout storage insert tray further comprises:
at least one partition positioned around the storage space, each configured to protect one of the at least one connector organizer.

17. The pulling container of claim 16, wherein the at least one partition is configured to provide a cable route for the cable to wrap around within the breakout storage insert tray.

18. The pulling container of claim 11, wherein:
the breakout storage insert tray includes three storage spaces, and
the at least one connector organizer can be removably coupled from any of the three storage spaces.

19. The pulling container of claim 11, wherein the breakout storage insert tray further includes:
at least one tie-down loop configured to reduce movement and displacement of the at least one cable during transportation and installation.

20. The pulling container of claim 11, further comprising:
a strain relief connected to a back end of the breakout storage insert tray and configured to provide bend radius protection for the at least one cable.
